(19) United States
(12) Patent Application Publication
(10) Pub. No.: US 2016/0240381 A1
(43) Pub. Date: Aug. 18, 2016

(54) PROCESS FOR MOLECULAR LAYER DOPING OF GERMANIUM SUBSTRATES

(71) Applicant: University College Cork, National University of Ireland, Cork, Cork (IE)

(72) Inventors: Brenda Long, Mungret (IE); Justin Holmes, Carrigaline (IE); Ray Duffy, Ballincollig (IE)

(21) Appl. No.: 15/043,360

(22) Filed: Feb. 12, 2016

Related U.S. Application Data
(60) Provisional application No. 62/116,877, filed on Feb. 16, 2015.

(51) Int. Cl. H01L 21/228; H01L 29/36; H01L 21/268; H01L 29/167; H01L 21/02; H01L 21/324

(52) U.S. Cl. CPC H01L 21/228; H01L 21/02057; H01L 21/324; H01L 21/2686; H01L 29/167; H01L 29/36

(57) ABSTRACT

A method of molecular layer doping of a germanium substrate comprises the steps of cleaning a surface of the germanium substrate to remove oxides, reacting the cleaned surface with a dopant solution comprising dopant material and a suitable solvent for the dopant at low temperature for a suitable period of time while irradiating the substrate with UV light, and thermal annealing of the germanium substrate.

### RELATED APPLICATION

This application claims the benefit of U.S. Provisional Application No. 62/116,877, filed on Feb. 16, 2015. The entire teachings of the above application(s) are incorporated herein by reference.

### BACKGROUND

State-of-the-art microprocessors contain several billion transistors over a ˜6 cm2 area. This enormous device density has been made possible by transistor scaling. However, in the last 10 to 15 years issues such as increased leakage current, directly related to device scaling, have necessitated radical changes in fabrication procedures, such as the transition from a silicon oxide dielectric to high-κ materials. Another considerable change has been the transitioning from planar to non-planar device architectures. Traditional architectures, with planar bulk substrates and highly doped channels for short-channel-effect control became problematic, due to excessive leakage currents. Non-planar devices (e.g. multigate FETs such as FinFETs), however, enabled better switching control, minimising leakage currents. Unfortunately, standard industrial techniques for doping were designed for the former.

Doping, or the introduction of impurity atoms, a fundamental process step in the fabrication of integrated circuits, allows tuning of the electrical properties of the semiconductor material. Current doping techniques, primarily ion implantation are destructive and too mono-directional for modern device architectures. Due to the directional nature of the ion beam and the non-planarity of the device it is impossible to uniformly dope the surface and there is residual damage (e.g. stacking faults) in the crystal structure of the device after annealing.

A related issue for scaled down non-planar devices, is that the ratio of surface:bulk atoms increases dramatically. Therefore, any process that is developed for doping these structures must be mild enough to maintain the integrity of the surface. If it is not and the surface roughness increases the concurrent generation of defects will have a dramatic effect on its electrical performance.

Therefore, a radically new, industrially viable, conformal and preferably non-destructive method for doping that minimises surface roughness is required.

Molecular Layer Doping (MLD), pioneered by the Javey Group has been shown to conformally and non-destructively dope planar Si substrates. See Appl. Phys. Lett. 100, 204102 (2012). Since then a number of III-V materials, including InGaAs, have been doped using molecular layers. See Szweda et al., THE ADVANCED SEMICONDUCTOR MAGAZINE VOL 16—NO 7, pp.36-38—SEPTEMBER/OCTOBER 2003. MLD is based on surface functionalisation and has the potential for precise atomistic control of the dopant position and composition on the surface of a semiconductor. Thermal decomposition of this molecular layer enables the freed-up dopant atoms to diffuse into the underlying semiconductor. Furthermore, minimal damage to the crystal structure of the underlying substrate occurs, due to the gentle nature of the process, while opening a path to deterministic doping techniques which have been recognised as an emerging candidate for regulated dopant delivery, ordered on the nanometre scale. See Akatsu et al., Materials Science in Semiconductor Processing, Vol. 9 (2006) 444-448.

As well as exploring new methods for doping, new materials with higher carrier mobilities then Si are also being investigated. To date improved performance has been achieved mostly through transistor scaling with the economic benefit of reusing existing infrastructure. For this trend to continue moving to a high carrier mobility material which can enable reduced power consumption (by delivering a fixed drive current and circuit speed at a reduced power supply voltage) is a priority. Materials such as graphene, transition metal dichalcogenides (TMDs) and III-Vs are being considered. Germanium (Ge) is a particularly attractive replacement for Si due to its enhanced electron and hole mobilities, and CMOS (complementary metal oxide semiconductor) compatibility, allowing Ge to be processed on existing Si technology platforms. Realistically, if Ge is to be used in future MOS technologies, it will likely be in the thin-body form.

To date MLD has not been demonstrated on Ge. In general, processing and chemical techniques employed by Si are broadly transferrable to Ge, however, assumptions made for Si do not necessarily apply to Ge. Due to the unstable oxide of Ge, the surface chemistry is vastly more challenging. For example, the temperature required to chemically bind dopant material to germanium is considerably higher (220° C.) than that required for Si (160° C.), and results in decomposition of the organic part of the doping material.

It is an object of embodiments of the invention to overcome at least one of the above-referenced problems.

### SUMMARY OF THE INVENTION

The Applicant has solved the technical problems of the literature and successfully chemically bonded dopant-containing-molecules in self-limiting monolayers to a germanium surface resulting in doped substrates after annealing. An embodiment of the invention provides doped germanium substrates and electronic device such as integrated circuits comprising the doped germanium substrate of the embodiment. The data presented below is generated using germanium as an example, but the embodiment applies to MLD of other germanium substrates, for example germanium alloys and germanium laminates. Material characterisation showed that the integrity of the surface was maintained and the underlying crystal structure was not damaged, while electrical characterisation showed several orders of magnitude decrease in resistance (FIGS. 2-4). The surface chemistry step in MLD of germanium can be achieved at low temperatures (less than 200° C.—thereby avoiding thermal decomposition of the dopant molecules and making it compatible with other parts of advanced integrated circuit processing) by performing the dopant/substrate reaction in the presence of UV light. The Applicant has surprisingly discovered that molecular layer doping of germanium substrates does not require a capping step prior to thermal annealing (FIG. 5).

Some embodiments of the invention provide a method of molecular layer doping of a germanium substrate, the method comprising the steps of: cleaning a surface of the germanium substrate to remove oxides; reacting the cleaned surface with a dopant solution comprising dopant material and a suitable solvent for the dopant at low temperature for a suitable period of time while irradiating the substrate with UV light; and subsequent thermal annealing of the germanium substrate.

Preferably, the reaction step is carried out at a temperature of less than 180° C.

Preferably, the reaction step is carried out at a temperature of less than 150° C.

Preferably, the reaction step is carried out at a temperature of less than 100° C.

Preferably, the reaction step is carried out at ambient temperature.

Preferably, the reaction step is carried out for at least 60 minutes, preferably at least 90 minutes, and ideally about two hours. Preferably, the reaction step is carried out at room temperature. However, it will be appreciated that if the reaction temperature is increased, the reaction time may be reduced.

Preferably, the UV irradiation is carried out for at least 60, 90 or 120 minutes. Typically, the UV irradiation is carried out during all or substantially all of the reaction step. Typically, the UV irradiation step employs UV light with a wavelength of 200-300 nm, preferably 230-280 nm, and ideally 250-260 nm.

In one embodiment, the process does not include a capping step. In another embodiment, the process includes a capping step after the reaction step and prior to the thermal annealing step in which a suitable capping layer is deposited on the substrate surface. Preferably, the capping layer comprises silicon dioxide. Other suitable capping layers include silicon nitride. Typically, the capping layer is deposited by means of sputtering, evaporation, or chemical vapour deposition (CVD).

Preferably, the germanium substrate is germanium, a germanium compound or alloy, or a germanium laminate.

Preferably, the dopant material is a molecule comprising one or more organic moieties covalently bound to a N-type or P-type dopant atom. Preferably, the dopant atoms are selected from arsenic, phosphorus, antimony, aluminum, gallium, boron and indium.

Preferably, the dopant material is a tri-allyl dopant (for example, tri-allyl arsenene) or a allyl diphenyl dopant oxide.

Preferably, the substrate is in the form of a wafer, preferably an un-patterned wafer a nanowire, or a fin (top-down nanowire typically fabricated by electron beam lithography).

Preferably, the thermal annealing step is rapid thermal annealing (RTA). Ideally, rapid thermal annealing is carried out between 600° C. and 700° C., preferably 630-670° C., optionally for a period of less than 10 or 5 seconds. Ideally, rapid thermal annealing is carried out between 640° C. and 660° C., optionally for a period of less than 5 seconds. Ideally, rapid thermal annealing is carried out at about 650° C. for a period of about 1 second.

An embodiment of the invention also provides a doped germanium substrate produced according to a method of the invention.

An embodiment of the invention also provides a germanium substrate doped by means of molecular layer doping and optionally having a doping concentration of at least 1×1018 cm-3 as determined using the method below.

An embodiment of the invention also provides a germanium substrate doped by means of molecular layer doping and optionally having a doping concentration of at least 5×1018 cm-3.

An embodiment of the invention also provides a Group III or Group V element doped germanium substrate.

An embodiment of the invention also provides a method of producing an electronic device, for example an integrated circuit, comprising the step of producing a doped germanium substrate according to a method of the embodiment, and then producing the electronic device using the doped germanium substrate. In one embodiment, the electronic device is an integrated circuit. In one embodiment, the electronic device is a microprocessor.

An embodiment of the invention also provides an electronic device comprising a doped germanium substrate according to the embodiment or formed according to a method of the invention. In one embodiment, the electronic device is an integrated circuit. In one embodiment, the electronic device is a microprocessor.

An embodiment of the invention also provides a method of passivating a surface of a germanium substrate comprising a step of molecular layer doping of the substrate according to a method of the embodiment.

An embodiment of the invention also relates to a method of fabricating an integrated circuit comprising a step of providing a germanium substrate, and molecular layer doping of the surface of the germanium substrate according to a method of the embodiment.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1: Scheme outlining details of the 5 step procedure for completing 1 MLD cycle.

FIG. 2: SIMS (solid line) v's ECV for carrier profiling of arsenic doped Ge performed by MLD. Rapid thermal annealing carried out using two thermal budgets as indicated. ECV and SIMS show the same doping profiles indicating that all the dopant that has diffused into Ge has been activated.

FIG. 3: Carrier profiling of arsenic doped Ge performed by MLD and rapid thermal annealing for 1, 10 and 100 s at 650° C. Inset shows molecule used. This experiment shows that increasing the thermal budget of the sample from 10 to 100 s can increase the total dose of dopant. The carrier concentration has reached a maximum at 650° C.

FIG. 4: Carrier profiling of two separate samples (green and red) of Ge doped by As after 1 MLD cycle (triangle) and after 2 MLD cycles (circle). RTA was carried out for 1 s at 650oC.

This highlights that MLD results are extremely reproducible. The total carrier concentration has reached a maximum after 1 MLD cycle.

FIG. 5: ECV carried out on samples with various (or no) SiO2 capping layers. RTA was carried out for 1 s at 650oC. Most interesting is the sample that had no capping layer. Although the incorporated carrier concentration was less than for some of the capped samples, the dopant concentration was still reasonable. Hence, these data show that it is possible to reduce the complexity of the MLD process, by reducing the number of steps required, i.e. no capping layer, which holds significant industrial value. A capping layer is not necessary to aid diffusion of the dopant into Ge during the annealing step.

FIG. 6: (a) Bottom-up e-beam fabricated 30 nm GeOI nanowire. (b) Cross-section TEM of 40 nm GeOI nanowire post MLD treatment. MLD treatment does not cause damage to the crystal structure of Ge

FIG. 7: I-V data showing scaling of current with reduced width of nanowire. Nanowires treated by MLD show an I-V response related to a decrease in resistance due to doping.

FIG. 8: Fin and nanowires structures

FIG. 9: Required surface dose to achieve C=1020 atoms/cm3 for a single sided functionalised fin, a double sided functionalised fin, and for a cylindrical nanowire.

FIG. 10: Required surface packing of dopant atoms, in terms of spacing, in order to achieve C=1020 atoms/cm3 for a single sided functionalised fin, a double sided functionalised fin, and for a cylindrical nanowire.

### DETAILED DESCRIPTION OF THE INVENTION

A description of example embodiments of the invention follows.

The teachings of all patents, published applications and references cited herein are incorporated by reference in their entirety.

### Definitions

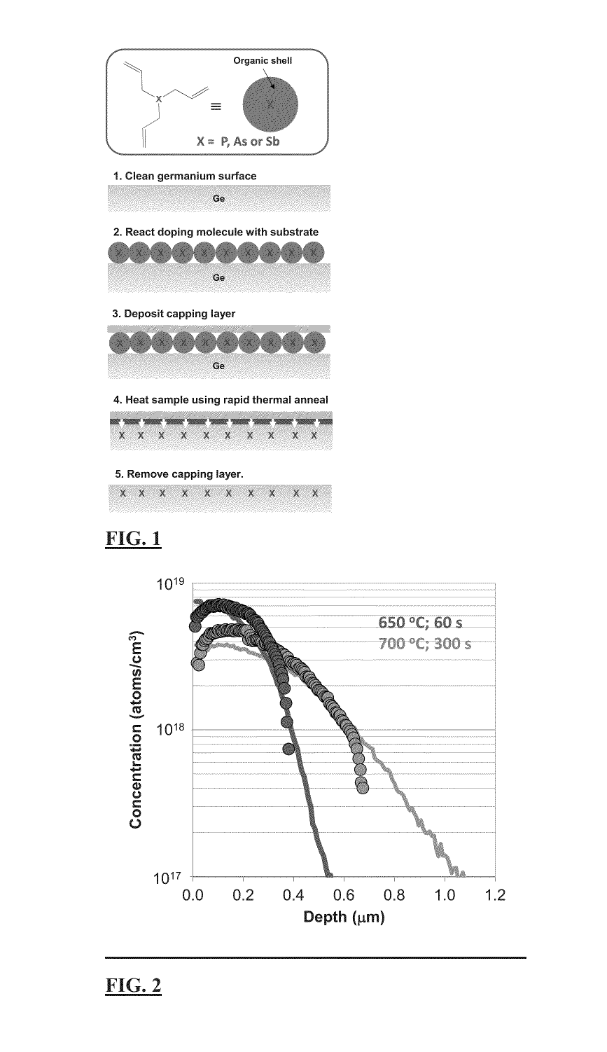

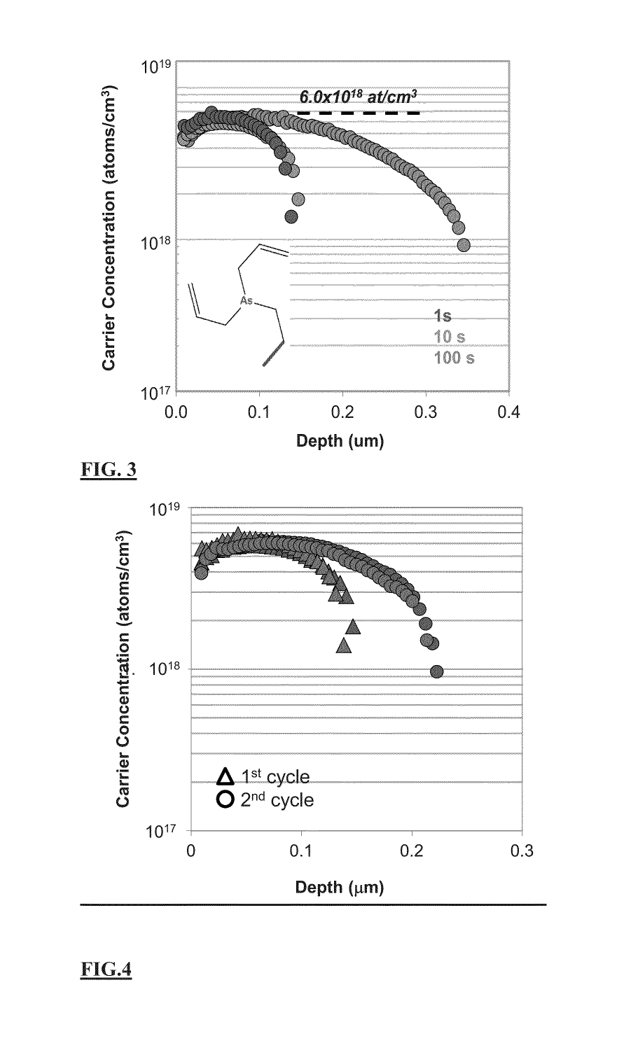

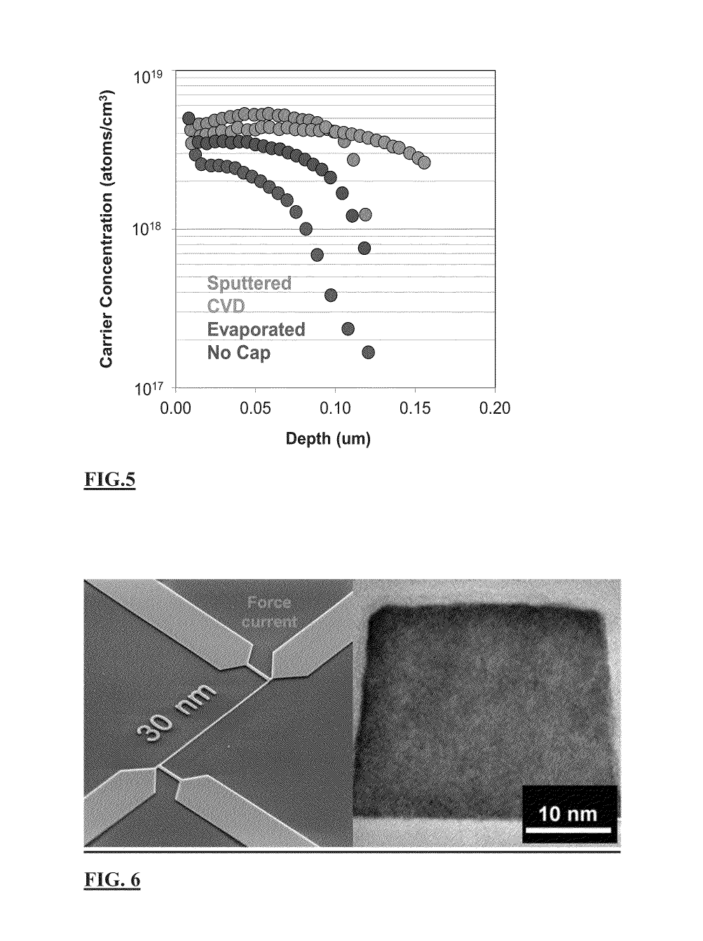

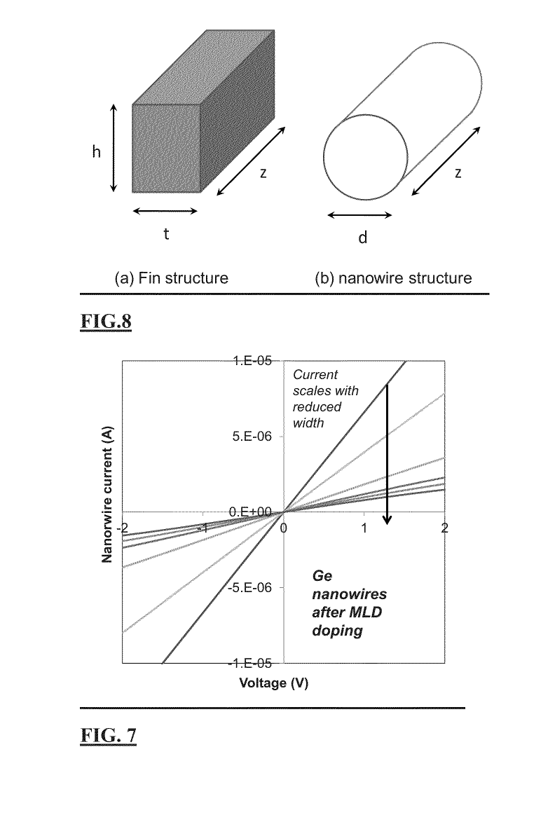

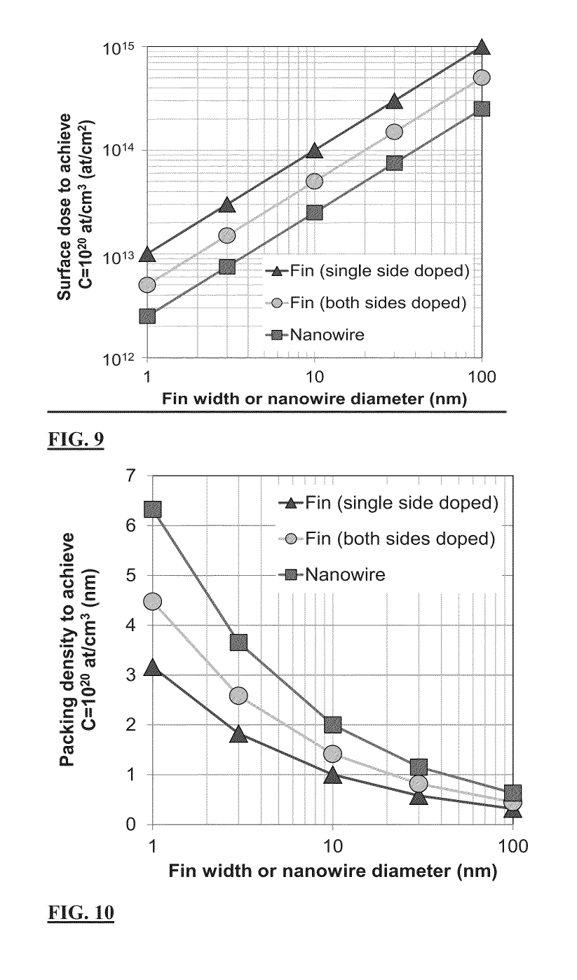

“Molecular layer doping” as used herein should be understood to mean the process described in Ho, J. C.; Yerushalmi, R.; Jacobson, Z. A.; Fan, Z.; Alley, R. L.; Javey, A., Controlled nanoscale doping of semiconductors via molecular monolayers. Nature Materials 2008, 7 (1), 62-67. See also Kong, E. Y. J.; Guo, P.; Gong, X.; Liu, B.; Yeo, Y. C., Toward conformal damage-free doping with abrupt ultrashallow junction: Formation of Si monolayers and laser anneal as a novel doping technique for InGaAs nMOSFETs. IEEE Transactions on Electron Devices 2014, 61 (4), 1039-1046; Meijer, J.; Vogel, T.; Burchard, B.; Rangelow, I. W.; Bischoff, L.; Wrachtrup, J.; Domhan, M.; Jelezko, F.; Schnitzler, W.; Schulz, S. A.; Singer, K.; Schmidt-Kaler, F., Concept of deterministic single ion doping with sub-nm spatial resolution. Applied Physics A: Materials Science and Processing 2006, 83 (2), 321-327. It involves chemically binding a doping molecule (comprising a suitable dopant atom (i.e. arsenic or phosphorus) covalently bound to an organic carrier) to a cleaned surface of a suitable substrate (i.e. silicon), and thermally annealing the surface to decompose the organic moiety leaving the dopant aton to diffuse into the substrate surface. It is described below with reference to FIG. 1 and heretofore has required application of a capping layer prior to the thermal annealing step and subsequent removal of the capping layer after thermal annealing.

“Germanium substrate” should be understood to mean a germanium-containing material including elemental germanium, compounds or alloys thereof, or a laminated material including a germanium layer, in which the germanium is typically in a crystalline or amorphous form, preferably in single crystal wafer form. Examples of Ge compounds or alloys include Si₁₋ₓGeₓ and GeTe (See Yang et al. Nano Lett. 2006, 6, 2679, and Yu et al. J. Am. Chem. Soc. 2006, 128, 8148), GeSn (Ge₁₋ₓSnₓ) (See 2012 Symp. VLSI Tech. Dig., 95), SiGeSn (Si_{1-x-y}GeₓSn_{y} (See Appl. Phys. Lett. 100, 204102 (2012)), SiGe (See Szweda et al. THE ADVANCED SEMICONDUCTOR MAGAZINE VOL 16—NO 7, pp. 36-38—SEPTEMBER/OCTOBER 2003). Examples of a laminate Ge material are germanium on insulator (GeOI) (See Akatsu et al. Materials Science in Semiconductor Processing, Vol. 9 (2006) 444-448), Ge thin films deposited on a carrier substrate (See Dutta et al Appl. Phys. Lett 105 (2014)).

“Cleaning the surface to remove oxides” means treating the surface to remove surface oxides. It is a well known step in MLD, and generally involves reacting the surface with a halogen, for example HF, and maintaining the cleaned surface in a non-reactive atmosphere.

“Suitable period of time” as applied to the reaction step means a period of time that is sufficient, at the reaction temperature, to allow a layer of dopant material chemically bind to the surface of the substrate.

“Dopant solution” means a solution of dopant material and a suitable solvent for the dopant material. When the dopant material is triallylarsenene,(TAA), a suitable solvent is IPA. Typically, the dopant solution is a weak solution (i.e. 1:4 to 1:6 TAA:IPA).

“Dopant material” means a molecule that can be charged or uncharged and comprises a suitable dopant atom bound to one or more organic moieties that are capable of reacting with germanium, for example organic moieties having a terminal C═C bond or a thiol group. An example of a dopant material is tri-allyl-dopant, for example tri-allyl arsine (TAA) or allyl diphenyl (dopant) oxide, for example allyl-diphenyl phosphine oxide. The purpose of the organic moiety is to chemically bind to the substrate surface, and thereby align the dopant atom with the surface of the substrate. Subsequent thermal annealing of the surface decomposes the organic moiety allowing the dopant atom diffuse into the surface of the substrate.

“Tri-allyl dopant” means, for example, tri-allyl(As), tri-allyl(Sb) or tri-allyl(P).

“Suitable dopant atom” means a Group III or Group V element suitable for use in doping germanium substrates, such as a N-type dopant like arsenic, phosphorus or antimony, or a P-type dopant like aluminum, gallium or indium.

“Capping layer” means a layer of material that covers the dopant material chemically bound to the substrate surface, and which remains in place during the thermal annealing step and is subsequently removed after thermal annealing. Examples of capping layers include SiO₂ and Si₃N₄. Use of capping layers is described in Ioannou et al., Appl. Phys. Lett. 93, 101910 (2008).The method according to an embodiment of the invention obviates the need for a capping step.

Experimental

All chemicals, purchased from Sigma-Aldrich were reagent grade and used as received. All blanket experiments were carried out on Ge(100) wafers purchased from Umicore, These substrates had p-type doping in the concentration range of 5-9×1016 at/cm-3. The nanowire samples were fabricated from undoped (100) germanium-on-insulator (GeOI), with a Ge thickness of 50 nm.

Material and Electrical Characterisation:

Atomic force microscopy (AFM) was implemented in tapping/non-contact mode at room temperature over a 3×53 μm scanning area. Cross-sectional transmission electron microscopy (TEM) was carried out using JEOL 2100 HRTEM operated at 200 kV. Cross-section samples were obtained by using FEI's Dual Beam Helios Nanolab system. For electrical characterisation Keithley 37100 and Keithley 2602 parameter analysers were used. Secondary ion mass spectrometry (SIMS) was performed on doped samples to obtain the total dopant concentration. SIMS analysis typically has a standard error of 20% in concentration and a 10% relative error from sample to sample. SIMS analysis was carried out done on a CAMECA IMS 4FE6 system, available at the UMS-CNRS Casting characterisation centre in Toulouse. Electrochemical capacitance voltage (ECV) profiling was used to determine the active carrier concentration in doped samples, using thiron as the etchant. For ECV data presented here, errors did not exceed 20%. X-ray photoelectron spectroscopy (XPS) was carried out with a VG Scientific Escalab MKII system using Mg X-rays at 1253 eV. Survey scans were performed using a pass energy of 200 eV and core level scans at a pass energy of 20 eV.

MLD Procedure

The experimental procedure for carrying out MLD is outlined broadly in FIG. 1. Synthesis of triallyarsenene (TAA) was carried out using a published procedure. See Phadnis, P. P.; Jain, V. K.; Klein, A.; Schurr, T.; Kaim, W., Tri(allyl)- and tri(methylallyl)arsine complexes of palladium(II) and platinum(II): Synthesis, spectroscopy, photochemistry and structures. New Journal of Chemistry 2003, 27 (11), 1584-1591. As TAA is a toxic material it should be handled with care using adequate PPE. Due to its unstable nature it must be stored in an inert atmosphere while minimising its exposure to air during transfer.

1. Substrate preparation: Ge was degreased by sonicating in acetone for 180 s, rinsed in IPA and dried under a stream of nitrogen, before being immersed in a 10% HF solution for 10 min, removed and dried under a stream of nitrogen. Ge was prepared immediately prior to reaction with TAA to minimise any possible re-oxidation.

2. Reaction of TAA with Ge: A solution of TAA in IPA (1:5) was degassed using 3× freeze/thaw cycles and transferred to a quartz flask containing the clean Ge substrate. The sample was irradiated for 2 h with UV light (λ54 nm) after which it was removed and rinsed several times with IPA and acetone. All functionalization experiments were carried out in an inert atmosphere.

3. Capping layer deposition: SiO2 capping layers were deposited used three different methods: 50 nm of oxide was sputtered, evaporated or deposited using CVD. In one sample, no capping layer was applied.

4. The annealing step was carried out in the presence if these oxides, after which they were removed using a standard BOE etch.

GeOI Nanowire Fabrication

Germanium-on-insulator (GeOI) substrates were patterned using a Raith e-Line Plus electron beam lithography (EBL) system and high resolution EBL resist known as hydrogen silsesquioxane (HSQ) purchased from Dow Corning. The substrates were firstly degreased by ultrasonicating them consequently in acetone and isopropylalcohol (IPA) solvents. They were then blown dry with a N2 gun and immersed in 1-2% hydrofluoric (HF) acid for 30-40 s and rinsed under flowing DI water. The substrates were subsequently dipped in 4.5 M HNO3 for 20 s, rinsed under DI water and immediately submerged in a solution of 7.5 M HCl for 10 min. This step provided Cl-terminated Ge surfaces. The substrates were then dried thoroughly under flowing N2 and a 1:2 concentration solution of HSQ in methylisobutyl ketone (MIBK) was spun on the substrates with 2000 rpm for 33 s (lid closed). This gives approximately 50 nm thick HSQ film on any substrate. The substrates were then baked at 120° C. for 3 min prior to EBL exposure.

EBL exposure was a two-step process where the first lithography step was used to expose only the high resolution fin structures. In the second step the contact pads for the four probes were exposed. To attain a highly focused beam for the first step, a 10 kV beam voltage and a 100 μm write-field was chosen. To avoid the large exposure time, the low resolution contact pads were written with a 1 kV beam voltage and 400 μm write-field. After the EBL exposures, the substrates were developed in 0.25 M NaOH and 0.7 M NaCl solution mixture for 15 s followed by 60 s rinse in DI water and 15 s immersion in IPA. For the second lithography step the substrates were Cl terminated as before, excluding the HF dip, and developed using the same method.

To transfer the HSQ pattern into the top Ge layer of the GeOI substrates, they were subjected to reactive ion etch (RIE) using Cl2 chemistry in Oxford Instruments Plasmalab 100 system.

GeOI Nanowire Doping

GeOI nanowire samples was degreased and immersed in HBr (10%) for 10 min to remove the native oxide and passivate with Br termination. The functionalisation procedure was the same as for blanket samples. No capping layer was applied as removing it would damage the underlying oxide in the GeOI.

While this invention has been particularly shown and described with references to example embodiments thereof, it will be understood by those skilled in the art that various changes in form and details may be made therein without departing from the scope of the invention encompassed by the appended claims.

What is claimed is:

1. A method of molecular layer doping of a germanium substrate, the method comprising the steps of:
cleaning a surface of the germanium substrate to remove oxides;
reacting the cleaned surface with a dopant solution comprising dopant material and a suitable solvent for the dopant at low temperature for a suitable period of time while irradiating the substrate with UV light; and
thermal annealing of the germanium substrate.

2. A method as claimed in claim 1 in which the reaction step is carried out at a temperature of less than 100° C.

3. A method as claimed in claim 1 in which the process does not include a capping step.

4. A method as claimed in claim 1 in which the germanium substrate is germanium, a germanium compound or alloy, or a germanium laminate.

5. A method as claimed in claim 1 in which the germanium substrate is selected from Ge, GeTe, SiGe, GeSn, SiGeSn, GeOI.

6. A method as claimed in claim 1 in which the dopant material comprises a Group III or Group V dopant atom selected from arsenic, phosphorus, antimony, aluminum, gallium, boron and indium bound to at least one reactive organic group.

7. A method as claimed in claim 1 in which the germanium substrate is in the form of a wafer, nanowire, or a fin.

8. A method as claimed in claim 1 in which rapid thermal annealing is carried out between 640° C. and 660° C., for a period of less than 5 seconds.

9. A germanium substrate doped with a Group III or Group V atom by means of molecular layer doping and having a doping concentration of at least 1×10¹⁸ cm⁻³.

10. A germanium substrate according to claim 9 and having a doping concentration of at least 5×10¹⁸ cm⁻³.

11. A germanium substrate as claimed in claim 9 in which the Group III or Group V atom is selected from arsenic, phosphorus, antimony, aluminum, gallium, boron and indium.

12. An electronic device comprising a doped germanium substrate according to claim 9.

13. An electronic device according to claim 12, in which the electronic device is an integrated circuit.

14. A germanium substrate produced according to the method of claim 1.

15. An electronic device comprising a doped germanium substrate produced according to a method of claim 1.

16. An electronic device according to claim 15, in which the electronic device is an integrated circuit.
